(19) United States
(12) Patent Application Publication
(10) Pub. No.: US 2024/0321734 A1
(43) Pub. Date: Sep. 26, 2024

(54) SEMICONDUCTOR DEVICE AND APPARATUS

(71) Applicant: Canon Kabushiki Kaisha, Tokyo (JP)

(72) Inventors: KOSEI UEHIRA, Tokyo (JP); HIROSHI SEKINE, Kanagawa (JP)

(21) Appl. No.: 18/591,057

(22) Filed: Feb. 29, 2024

(30) Foreign Application Priority Data
Mar. 22, 2023 (JP) 2023-045788

(51) Int. Cl. H01L 23/528; H01L 29/06; H01L 31/0224; H01L 31/107

(52) U.S. Cl. CPC H01L 23/528; H01L 29/0692; H01L 31/022408; H01L 31/107

(57) ABSTRACT

A semiconductor device that includes a semiconductor layer including first and second surfaces, a first insulator arranged on the first surface and a second insulator arranged on the second surface is provided. The semiconductor layer includes first and second portions which are electrically separated in the semiconductor layer by a trench. The first portion includes a first region of a first conductivity type at the first surface and a second region of a second conductivity type at the second surface. The second portion includes a third region of the first conductivity type at the first surface and a fourth region of the second conductivity type at the second main surface. A first conductive path connected the first and third regions is arranged in the first insulator and a second conductive path connected the second and fourth regions is arranged in the second insulator.

### BACKGROUND OF THE INVENTION

### Field of the Invention

The present invention relates to a semiconductor device and an apparatus.

### Description of the Related Art

Japanese Patent Laid-Open No. 2020-065016 describes a semiconductor device including a separation region where an insulating film is embedded in a groove extending through a semiconductor layer.

In the arrangement in which the semiconductor layer is separated using the separation region, a problem may occur in a semiconductor element arranged in the semiconductor layer due to charging or the like.

Some embodiments of the present invention provide a technique advantageous in suppressing occurrence of a problem of a semiconductor element.

### SUMMARY OF THE INVENTION

According to some embodiments, a semiconductor device that comprises a semiconductor layer comprising a first main surface and a second main surface on an opposite side of the first main surface, a first insulating layer arranged in contact with the first main surface, and a second insulating layer arranged in contact with the second main surface, wherein the semiconductor layer includes a first portion and a second portion, which are electrically separated in the semiconductor layer by a trench extending through the semiconductor layer, and a semiconductor element is arranged in the second portion, the first portion includes a first semiconductor region of a first conductivity type which forms a part of the first main surface, and a second semiconductor region of a second conductivity type opposite to the first conductivity type which forms a part of the second main surface, the second portion includes a third semiconductor region of the first conductivity type which forms a part of the first main surface, and a fourth semiconductor region of the second conductivity type which forms a part of the second main surface, a first conductive path configured to electrically connect the first semiconductor region and the third semiconductor region is arranged in the first insulating layer, and a second conductive path configured to electrically connect the second semiconductor region and the fourth semiconductor region is arranged in the second insulating layer, is provided.

Further features of the present invention will become apparent from the following description of exemplary embodiments (with reference to the attached drawings).

### BRIEF DESCRIPTION OF THE DRAWINGS

FIG. 1 is a plan view showing an arrangement example of a semiconductor device according to an embodiment;

FIG. 2 is a sectional view showing an arrangement example of the semiconductor device shown in FIG. 1;

FIG. 3 is a sectional view showing the arrangement example of the semiconductor device shown in FIG. 1;

FIGS. 4A to 4C are views each showing the layout of a chip guard ring of the semiconductor device shown in FIG. 1;

FIG. 5 is a view for explaining the effect of the semiconductor device shown in FIG. 1;

FIG. 6 is a view for explaining the effect of the semiconductor device shown in FIG. 1;

FIG. 7 is a view for explaining the effect of the semiconductor device shown in FIG. 1;

FIG. 8 is a view for explaining the effect of the semiconductor device shown in FIG. 1;

FIG. 9 is a view for explaining the effect of the semiconductor device shown in FIG. 1;

FIG. 10 is a view for explaining the effect of the semiconductor device shown in FIG. 1;

FIG. 11 is a sectional view showing an arrangement example of the semiconductor device shown in FIG. 1;

FIGS. 12A to 12C are views for explaining a method of manufacturing the semiconductor device shown in FIG. 1:

FIGS. 13A and 13B are views for explaining the method of manufacturing the semiconductor device shown in FIG. 1;

FIG. 14 is a sectional view showing an arrangement example of the semiconductor device shown in FIG. 1;

FIG. 15 is a sectional view showing an arrangement example of the semiconductor device shown in FIG. 1;

FIG. 16 is a sectional view showing an arrangement example of the semiconductor device shown in FIG. 1;

FIG. 17 is a plan view showing a modification of the semiconductor device shown in FIG. 1;

FIG. 18 is a sectional view showing an arrangement example of the semiconductor device shown in FIG. 17;

FIG. 19 is a sectional view showing the arrangement example of the semiconductor device shown in FIG. 17;

FIG. 20 is a sectional view showing an arrangement example of the semiconductor device shown in FIG. 1;

FIG. 21 is a sectional view showing an arrangement example of the semiconductor device shown in FIG. 1;

FIG. 22 is a sectional view showing an arrangement example of the semiconductor device shown in FIG. 1;

FIG. 23 is a sectional view showing an arrangement example of the semiconductor device shown in FIG. 1;

FIG. 24 is a sectional view showing an arrangement example of the semiconductor device shown in FIG. 1;

FIG. 25 is a sectional view showing an arrangement example of the semiconductor device shown in FIG. 1;

FIG. 26 is a sectional view showing an arrangement example of the semiconductor device shown in FIG. 1; and

FIG. 27 is a view showing an arrangement example of an apparatus incorporating the semiconductor device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

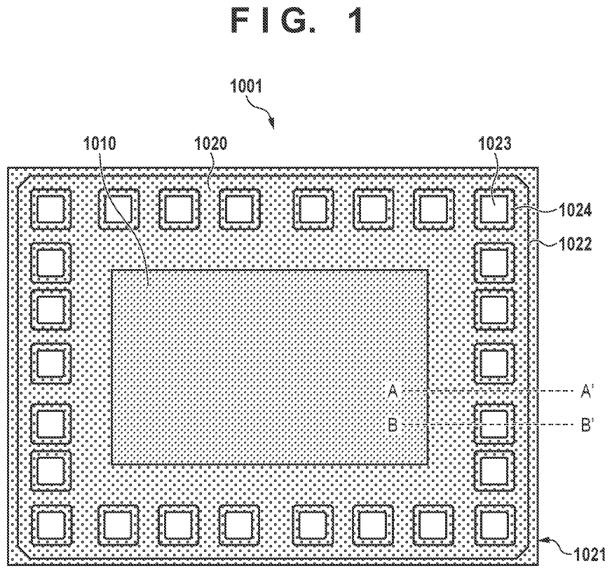

With reference to FIGS. 1 to 26, a semiconductor device according to an embodiment of the present disclosure will be described. In the embodiment described below, a description will be given while taking a photoelectric conversion device as an example of the semiconductor device. However, the present disclosure is not limited to this, and the present disclosure is applicable to a processing device, a storage device, a light emitting device, and the like, each including a semiconductor element, of various logic circuits, storage circuits, display circuits, and the like. More specifically, the present disclosure is applicable to all semiconductor devices each having a structure in which a semiconductor layer is electrically separated in the semiconductor layer as will be described below.

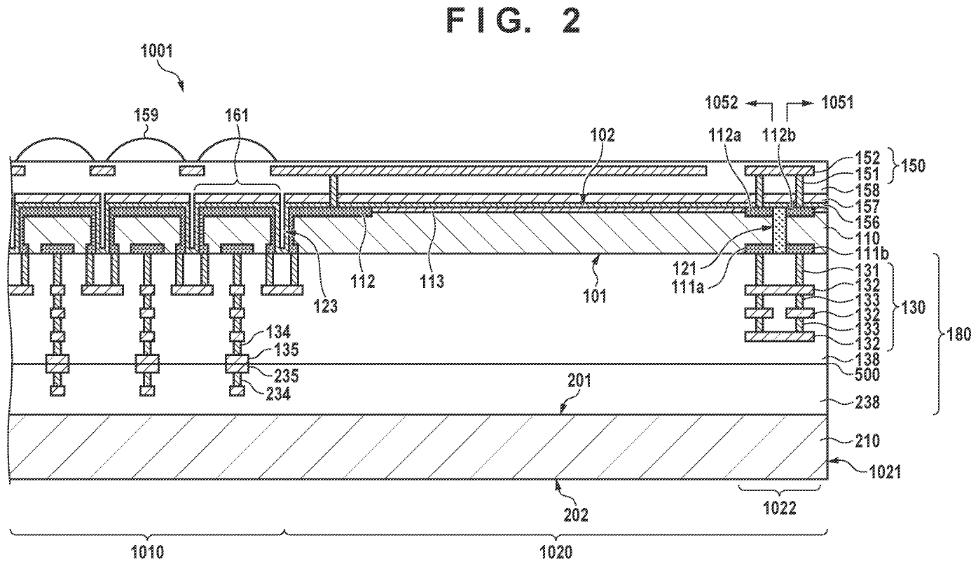

FIG. 1 is a top view showing an arrangement example of a semiconductor device 1001 according to this embodiment. The semiconductor device 1001 includes a pixel portion 1010 where a plurality of pixels are arranged, and a peripheral circuit portion 1020 where a circuit for driving the pixel portion is arranged. In the peripheral circuit portion 1020, a chip guard ring portion 1022 is arranged along an outer edge 1021 of the semiconductor device 1001. The chip guard ring portion 1022 can be arranged so as to surround the outer edge portion of the semiconductor device 1001 as shown in FIG. 1. Further, in the peripheral circuit portion 1020, pad guard ring portions 1024 are arranged such that each pad guard ring portion 1024 surrounds each pad opening portion 1023 configured to expose an electrode pad for external connection. Each of the chip guard ring portion 1022 and the pad guard ring portions 1024 is provided for the purpose of moisture resistance of a semiconductor layer 110 (shown in FIG. 2 and subsequent drawings) of the semiconductor device 1001.

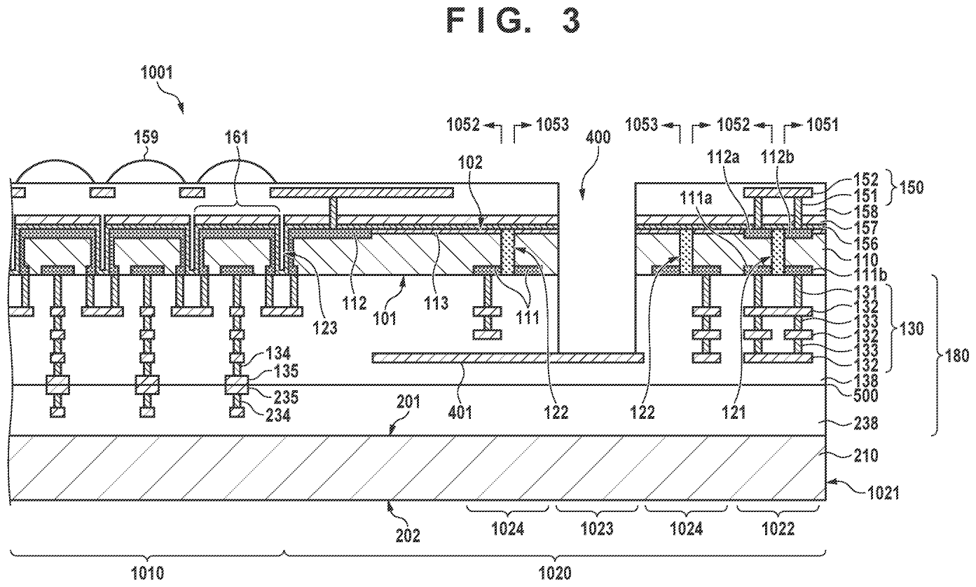

FIG. 2 is a sectional view showing the arrangement example taken along a line A-A′ in FIG. 1. FIG. 3 is a sectional view showing the arrangement example taken along a line B-B′ in FIG. 1. FIG. 2 is the sectional view not including the pad opening portion 1023, and FIG. 3 is the sectional view including the pad opening portion 1023.

As shown in FIGS. 2 and 3, the semiconductor device 1001 includes the semiconductor layer 110 including a main surface 101 and a main surface 102 on the opposite side of the main surface 101, an insulating layer 180 arranged in contact with the main surface 101, and an insulating layer 158 arranged in contact with the main surface 102. The semiconductor device 1001 also includes a semiconductor layer 210 stacked on the semiconductor layer 110 via the insulating layer 180. The semiconductor layer 210 includes a main surface 201 arranged in contact with the insulating layer 180, and a main surface 202 on the opposite side of the main surface 201. It can also be said that the semiconductor device 1001 has a stacked structure in which the semiconductor layer 110 and the semiconductor layer 210 are stacked.

The insulating layer 180 arranged between the semiconductor layer 110 and the semiconductor layer 210 includes an insulating layer 138 in contact with the main surface 101 of the semiconductor layer 110, and an insulating layer 238 in contact with the main surface 201 of the semiconductor layer 210. The insulating layer 138 and the insulating layer 238 are joined at a joint surface 500 via joint metals 135 and 235 and joint vias 134 and 234.

For the semiconductor layer 110, a semiconductor substrate made of silicon or the like having an n-type conductivity can be used. In the pixel portion 1010, a plurality of pixels 161 are arranged in the semiconductor layer 110. The pixels 161 can include, for example, a photodiode, an avalanche photodiode, and the like. The pixels 161 are separated from each other by inter-pixel trenches 123. In the pixel portion 1010, on the main surface 102 side of the semiconductor layer 110, in order to improve the light collection efficiency, a microlens 159 can be arranged on the insulating layer 158 so as to correspond to each pixel 161. An optical film 157 for preventing reflection is arranged between the main surface 102 of the semiconductor layer 110 and the insulating layer 158. A fixed charge film 156 to be described later may be arranged between the main surface 102 of the semiconductor layer 110 and the optical film 157. The fixed charge film 156 can be arranged in contact with the main surface 102 of the semiconductor layer 110. Further, a wiring layer including a wiring pattern 152 is arranged in the insulating layer 158. The wiring pattern 152 may be used as a light shielding pattern to prevent color mixing in the pixel portion 1010. The wiring pattern 152 may or may not have both a light shielding function and an electric connecting function.

The semiconductor layer 110 is divided into a portion 1051 and a portion 1052, which are electrically separated in the semiconductor layer 110 by a trench 121 extending through the semiconductor layer 110 arranged in the chip guard ring portion 1022. In the portion 1052, semiconductor elements such as the pixels 161 are arranged. It can also be said the pixel portion 1010 is located in the portion 1052. The portion 1051 includes an n-type semiconductor region 111b forming a part of the main surface 101 of the semiconductor layer 110, and a p-type semiconductor region 112b forming a part of the main surface 102 of the semiconductor layer 110, whose conductivity type is opposite to the n type. The portion 1052 includes an n-type semiconductor region 111a forming a part of the main surface 101 of the semiconductor layer 110, and a p-type semiconductor region 112a forming a part of the main surface 102 of the semiconductor layer 110.

In the semiconductor layer 110, in order to prevent chipping, the trench 121 is arranged in the chip guard ring portion 1022 so as to surround the inside of the outer edge 1021 of the semiconductor device 1001. That is, the portion 1051 is arranged so as to surround the portion 1052. Further, the portion 1051 forms the outer edge 1021 of the semiconductor device 1001. An insulator such as silicon oxide or silicon nitride is embedded in the trench 121. Therefore, in the semiconductor layer 110, the portion 1051 and the portion 1052 are electrically insulated as has been described above. That is, the semiconductor region 111a and the semiconductor region 111b are electrically separated in the semiconductor layer 110. Similarly, the semiconductor region 112a and the semiconductor region 112b are electrically separated in the semiconductor layer 110. However, a conductive path 130 using conductive members 131 and 133 and wiring patterns 132 for electrically connecting the semiconductor region 111a and the semiconductor region 111b is arranged in the insulating layer 180. Further, a conductive path 150 using a conductive member 151 and the wiring pattern 152 for electrically connecting the semiconductor region 112a and the semiconductor region 112b is arranged in the insulating layer 158. With this, the portions 1051 and 1052 of the semiconductor layer 110 are electrically connected, thereby preventing chipping of the semiconductor layer 110 and preventing the end portion (portion 1051) of the semiconductor layer 110 from entering a floating state. In this embodiment, a description will be given assuming that the conductivity types of the semiconductor regions 111a and 111b are the n type, and the conductivity types of the semiconductor regions 112a and 112b are the p type. However, the conductivity types are not limited to this, and the conductivity types of the semiconductor regions 111a and 112a may be the p type, and the conductivity types of the semiconductor regions 111b and 112b may be the n type.

The semiconductor element such as the pixel 161 arranged in the pixel portion 1010 of the semiconductor layer 110 may include a p-type semiconductor region 112 as shown in FIGS. 2 and 3. The p-type semiconductor region 112a in the chip guard ring portion 1022 may be electrically connected to the p-type semiconductor region 112 in the pixel portion 1010 via a hole inducing layer 113 induced in the main surface 102 of the semiconductor layer 110 by the fixed charge film 156 made of aluminum oxide or the like having negative fixed charges. When the pixel 161 is an avalanche photodiode and the semiconductor device 1001 is a single photon avalanche diode (SPAD) sensor, for example, a voltage of −30 V is applied to the p-type semiconductor region 112 in the pixel portion 1010. When the pixel 161 is a photodiode and the semiconductor device 1001 is a COMS sensor, for example, a voltage of −5 V is applied to the p-type semiconductor region 112 in the pixel portion 1010. Due to this voltage application, in the pixel portion 1010, light entering from the main surface 102 side of the semiconductor layer 110 is photoelectrically converted into electronic information. Thus, image capturing can be performed.

Here, the p-type semiconductor regions 112a and 112b may be formed by implanting a p-type dopant. Alternatively, the hole inducing layer 113 generated in the main surface 102 of the semiconductor layer 110 by the fixed charge film 156 may be used as the p-type semiconductor regions 112a and 112b. Alternatively, for example, a p-type dopant may be implanted in a portion indicated as the hole inducing layer 113. In this case, the fixed charge film 156 may or may not be arranged.

For the conductive paths 130 and 150, the conductive path may be formed using the wiring pattern 152 arranged in one wiring layer, like the conductive path 150. Alternatively, the conductive path may be formed using the wiring patterns 132 arranged in a plurality of wiring layers, like the conductive path 130. The conductive paths 130 and 150 may have appropriate arrangements in accordance with the arrangement of the wiring layers arranged the insulating layers 158 and 180, respectively. When the wiring patterns 132 arranged in the plurality of wiring layers are used, like the conductive path 130, since multiple conductive paths are arranged in parallel, a stronger electric connection path can be formed.

As shown in FIG. 3, an electrode pad 401 for external connection is arranged in the insulating layer 180 in the pad opening portion 1023. In the semiconductor layer 110, an opening portion 400 extending through the semiconductor layer 110 and configured to expose the electrode pad is arranged. The opening portion 400 extends from the surface of the insulating layer 158 of the semiconductor device 1001 to the electrode pad 401, and a wiring for external connection is connected to the electrode pad 401 by processing such as wire bonding.

Also in the pad opening portion 1023, the pad guard ring portion 1024 arranged with a trench 122 is arranged so as to surround the opening portion 400. The trench 122 is arranged to prevent chipping in the pad opening portion 1023. In this case, the semiconductor layer 110 includes, between the opening portion 400 and the portion 1052 where the semiconductor elements such as the pixels 161 are arranged, a portion 1053 arranged so as to surround the opening portion 400. In the semiconductor layer 110, the trench 122 extending through the semiconductor layer 110 so as to electrically separate the portion 1052 and the portion 1053 in the semiconductor layer 110 is arranged. Similar to the trench 121, an insulator such as silicon oxide or silicon nitride is embedded in the trench 122. Therefore, the portion 1053 of the semiconductor layer 110 exposed to the opening portion 400 is electrically separated from the portion 1052 and in a floating state.

In the portion 1053 in the floating state, an unintended electric field may be generated between it and other portions 1051 and 1052, or an overcurrent may be generated when a voltage is applied to the semiconductor element. However, since the opening portion 400 is formed using plasma etching with a large amount of plasma charges, there is a concern that the reliability of the semiconductor element decreases. Therefore, in this embodiment, the portion 1053 is electrically separated from the portions 1051 and 1052. However, the present invention is not limited to this, and the portion 1053 may be electrically connected to the portions 1051 and 1052 as will be described later.

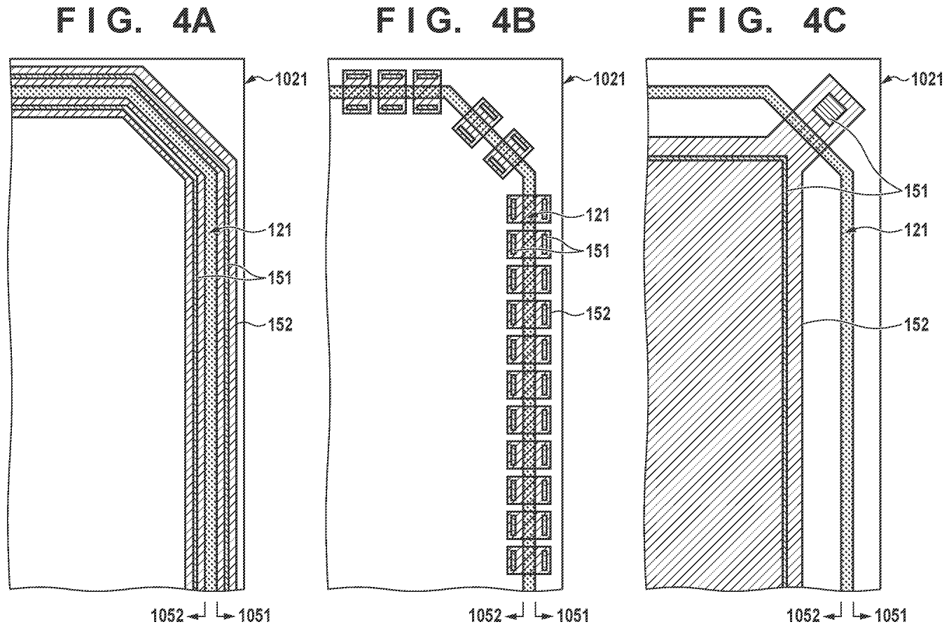

Each of FIGS. 4A to 4C is an enlarged view of the top view of the semiconductor device 1001 shown in FIG. 1 near the outer edge 1021 of the semiconductor device 1001. In the arrangement shown in FIG. 4A, the conductive member 151 is arranged along the trench 121, and the wiring pattern 152 is laid out so as to cover the conductive member 151. It can be said that the arrangement shown in FIG. 4A is an arrangement that can most easily avoid the floating state of the portion 1051 of the semiconductor layer 110 which is arranged so as to form the outer edge 1021 of the semiconductor device 1001. The conductive member 151 and the wiring pattern 152 also have a function of improving the moisture resistance of the insulating layer 158. It can be said that the arrangement shown in FIG. 4A is the arrangement that is most effective in improving the moisture resistance as well.

Here, the trench 121 is bent at 45 in the corner portion of the semiconductor device 1001 to reduce variations in the line width and depth of the trench 121. For example, if the trench 121 is bent at a right angle, when forming the trench 121, the line width increases in the portion where the trench 121 is bent. In this case, voids are highly likely to occur when embedding the insulator. This may lead to a decrease in moisture resistance of the chip guard ring portion 1022. In order to suppress a decrease in moisture resistance, the trench 121 is arranged obliquely with respect to the direction along the outer edge 1021 of the semiconductor device 1001 in the corner portion of the semiconductor device 1001.

In the arrangement shown in FIG. 4B, with respect to the trench 121, the portion 1051 and the portion 1052 are intermittently electrically connected via the conductive member 151 and the wiring pattern 152. Even if the connection is intermittent, it functions as the conductive path for flowing electricity. The connected regions are appropriately designed in accordance with the amount of current generated by the voltage applied to the semiconductor element arranged in the portion 1052.

In the arrangement shown in FIG. 4C, the conductive path is provided only in the corner portion of the semiconductor device 1001. Even with this arrangement, an effect to be described later can be obtained. Further, in the arrangement shown in FIG. 4C, the wiring pattern 152 used for the conductive path is also used for the light shielding pattern arranged in the portion 1052, and the conductive path and the light shielding pattern are connected. In this case, a conductive path having a higher conductivity than the hole inducing layer 113 in the semiconductor layer 110 is formed between the pixel portion 1010 arranged in the portion 1052 and the semiconductor region 112a. Accordingly, the time lag until the voltage applied to the semiconductor region 112 of the pixel 161 arranged in the pixel portion 1010 is applied to the portion 1051 decreases, so that the floating state of the portion 1051 can be quickly avoided.

The arrangement of the conductive path on the main surface 102 side of the semiconductor layer 110 has been described with reference to FIGS. 4A to 4C. However, this can also be applied to the conductive path on the main surface 101 side of the semiconductor layer 110 by replacing the conductive member 151 and the wiring pattern 152 with the conductive members 131 and 133 and the wiring patterns 132, respectively. Further, the arrangements shown in FIGS. 4A to 4C may be laid out in a complex combination, as appropriate.

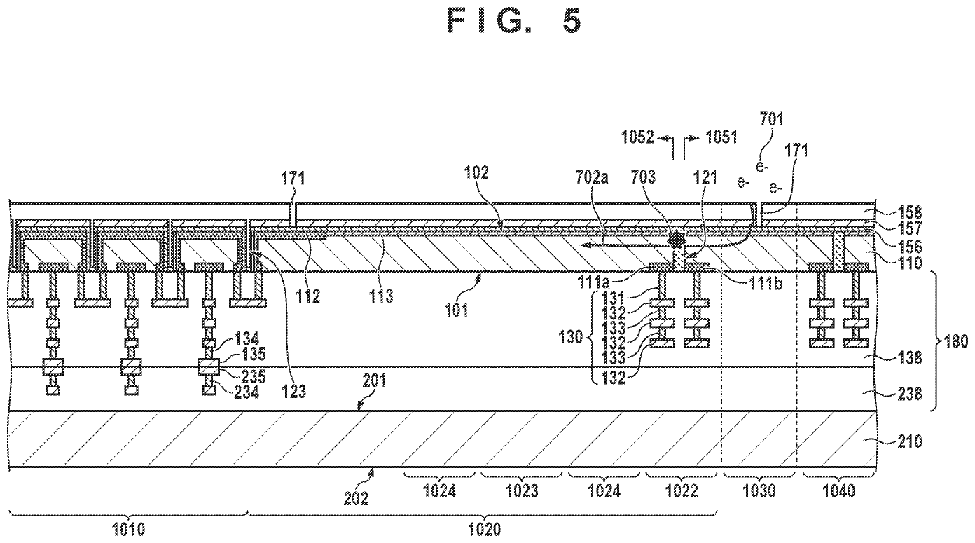

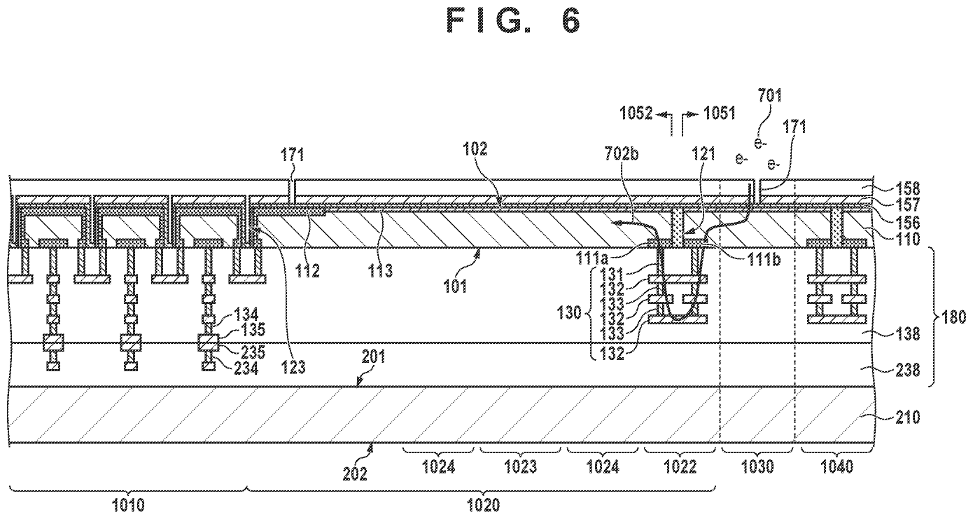

Next, effects of this embodiment will be described. Each of FIGS. 5 and 6 shows a plasma etching step for forming a via 171 in which the conductive member 151 is to be arranged, which is performed in the manufacture of the semiconductor device 1001. The semiconductor device 1001 is finally diced and divided into pieces in a scribe region 1030. In the step shown in each of FIGS. 5 and 6, since the semiconductor device 1001 has not been divided into pieces yet, another chip 1040 of the semiconductor device 1001 adjacent via the scribe region 1030 is arranged.

FIG. 5 shows a case in which the conductive path 130 using the conductive members 131 and 133 and the wiring patterns 132 is not arranged. During formation of the via 171, negative charges 701 from a plasma enter the insulating layer 158 and the surface of a resist (not shown) used as an etching mask pattern, so that the insulating layer 158 and the resist are charged. The etching process is not completely uniform in the plane of the wafer.

Accordingly, a via 171b formed in the scribe region 1030 may reach the semiconductor layer 110 before a via 171a formed in the peripheral circuit portion 1020. If the via 171b reaches the semiconductor layer 110, a large current flows from the via 171b through an electric path 702a, and the trench 121 may be damaged in a portion 703 on the electric path 702a. If the trench 121 is damaged, the moisture resistance of the chip guard ring portion 1022 decreases. A decrease in moisture resistance of the chip guard ring portion 1022 can cause a problem of the semiconductor element such as the pixel 161 arranged in the semiconductor layer 110 of the semiconductor device 1001. This can cause a problem such as a decrease of the reliability of the semiconductor device 1001.

To the contrary, as shown in FIG. 6, in a case in which the conductive path 130 using the conductive members 131 and 133 and the wiring patterns 132 is arranged, an electric path 702b passing from the via 171 through the conductive path 130 can suppress a possibility of damage of the trench 121. As a result, occurrence of a problem of the semiconductor element arranged in the semiconductor layer 110 is suppressed, and the reliability of the semiconductor device 1001 improves. That is, providing the conductive path 130 between the portions 1051 and 1052 of the semiconductor layer 110, which are electrically separated by the trench 121, is effective as a countermeasure against a problem caused by a part of the semiconductor layer 110 entering the floating state.

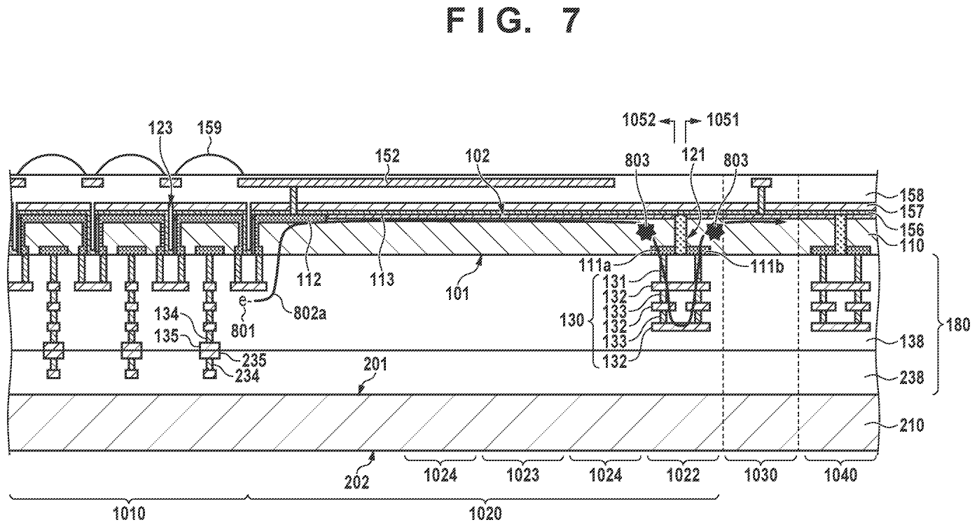

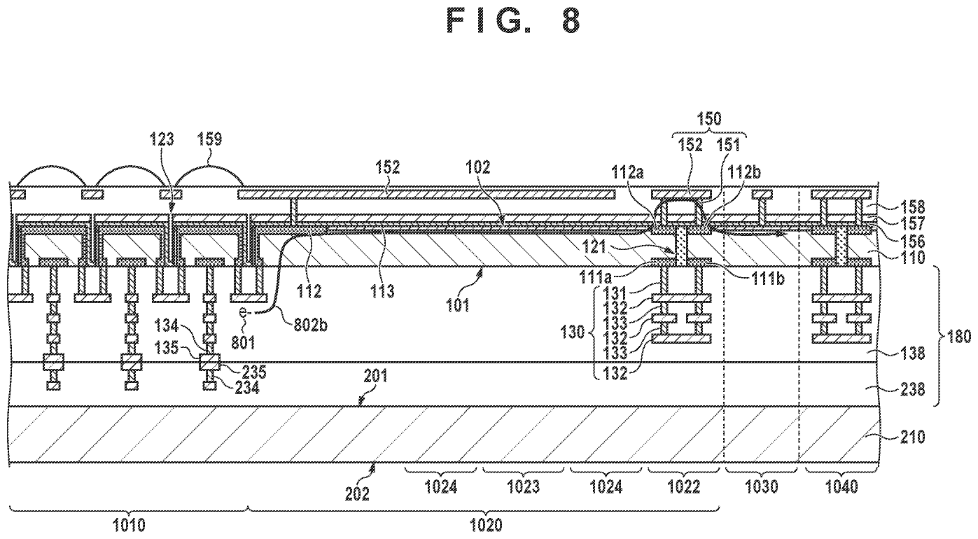

Next, with reference to FIGS. 7 and 8, another effect different from the effect described above will be described. Each of FIGS. 7 and 8 assumes a test step performed after the semiconductor device 1001 is formed and before the semiconductor device 1001 is divided into pieces. FIG. 7 shows a case in which the conductive path 150 using the conductive member 151 and the wiring pattern 152 is not arranged. In the arrangement shown in FIG. 7, a minus potential 801 applied to the pixel portion 1010 passes through an electric path 802a to avoid the floating state. However, in the arrangement shown in FIG. 7, a p-n junction portion 803 exists in the chip guard ring portion 1022. Accordingly, in a case in which a current flows in a direction of reverse junction, the floating state due to passing through the electric path 802a cannot be avoided, and a problem caused by the floating state as described above may occur. On the other hand, in a case in which a current flowing in a direction of forward junction, if a large current flows, the p-n junction portion 803 may become a light emission source, and the current may be photoelectrically converted by the pixel 161. This may affect an obtained image.

To the contrary, as shown in FIG. 8, in a case in which the conductive path 150 using the conductive member 151 and the wiring pattern 152 is arranged, even if a voltage is applied, an electric path 802b not passing through the p-n junction portion 803 is formed. Hence, the problem as described above is solved. That is, providing the p-type conductive path 150 and the n-type conductive path 130 between the portions 1051 and 1052 of the semiconductor layer 110 electrically separated by the trench 121 has effects as a countermeasure against a problem caused by a part of the semiconductor layer 110 entering the floating state, and a countermeasure against light emission in the p-n junction portion 803.

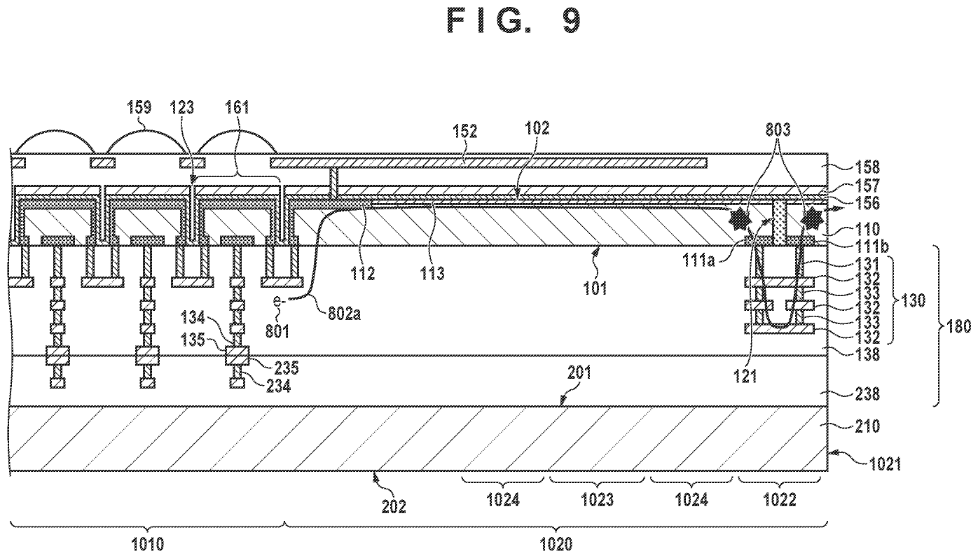

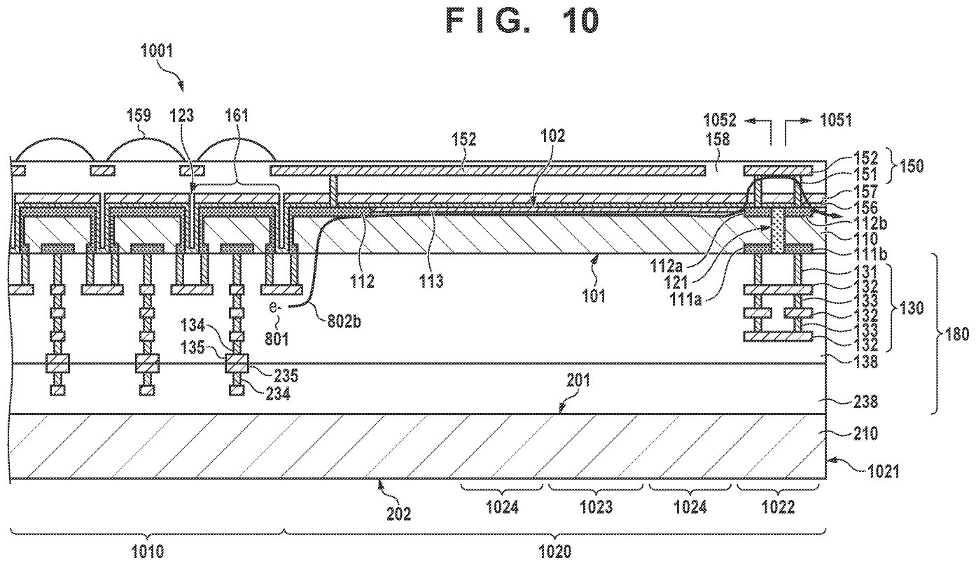

With reference to FIGS. 9 and 10, a modification of the effect described with reference to FIGS. 7 and 8 will be described. Each of FIGS. 9 and 10 is a view for explaining an effect in an operation after the semiconductor device 1001 is divided into pieces.

As has been described above, FIGS. 7 and 8 assume, for example, testing at a wafer level. The amount of current generated when a voltage is applied becomes large since it includes the influence of the capacitances from the scribe region 1030 and the adjacent chip 1040. As shown in FIG. 9, even after dicing (dividing into pieces), the adjacent chip 1040 is removed, and the capacitance of the portion 1051 decreases. However, as in the arrangement shown in FIG. 7, the influence of the capacitance of the portion 1051 remains if the portion 1051 is in the floating state. To prevent this, instead of providing only the electric path 802a as in the arrangement shown in FIG. 9, the electric path 802b is provided as in the arrangement according to this embodiment shown in FIG. 10. With this, a problem caused by the floating state and an influence on an image obtained when the p-n junction portion 803 becomes a light emission source can be suppressed. That is, this has effects as a countermeasure against a problem caused by a part of the semiconductor layer 110 entering the floating state, and a countermeasure against light emission in the p-n junction portion 803.

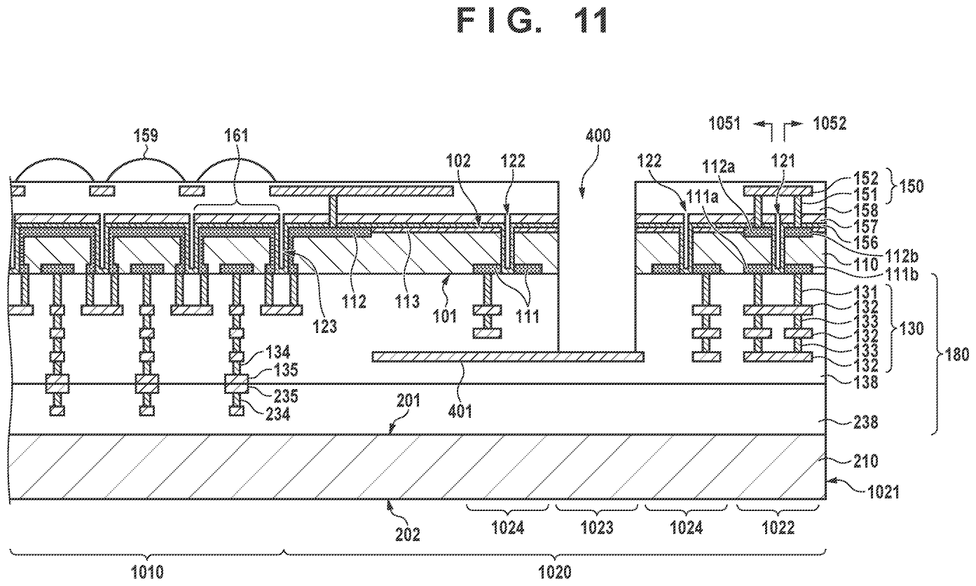

FIG. 11 is a view showing a modification of the sectional view shown in FIG. 3. In the arrangement shown in FIG. 3, it has been described that each of the trench 121 arranged in the chip guard ring portion 1022 and the trench 122 arranged in the pad guard ring portion 1024 is filled with an insulator such as silicon oxide or silicon nitride. On the other hand, in the arrangement shown in FIG. 9, the trench 121 and the trench 122 have an arrangement similar to that of the inter-pixel trench 123 arranged in the pixel portion 1010. The remaining arrangement may be similar to that described above, so that the arrangement different from the above-described arrangement will be mainly described here, and a description of the arrangement that may be similar to the above-described arrangement will be omitted, as appropriate.

In the arrangement shown in FIG. 11, in each of the trenches 121 and 122 and the inter-pixel trench 123, a metal or a metal oxide is arranged between the insulator such as silicon oxide or silicon nitride and the surface of each of the trenches 121 and 122 and the inter-pixel trench 123. For example, a metal oxide such as aluminum oxide (Al₂O₃) or hafnium oxide (HfO₂), which is also used as the fixed charge film 156, may be arranged on the surface of each of the trenches 121 and 122 and the inter-pixel trench 123. Alternatively, a metal such as titanium (Ti), titanium nitride (TiN), tungsten (W), copper (Cu), aluminum (Al), nickel (Ni), or rubidium (Rb), an alloy thereof, or a metal-containing substance thereof may be arranged on the surface of each of the trenches 121 and 122 and the inter-pixel trench 123.

For example, when forming aluminum oxide used for the fixed charge film 156, aluminum oxide is formed on the main surface 102 of the semiconductor layer 110 and the surfaces of the trenches 121 and 122 and the inter-pixel trench 123. Then, an insulator such as silicon oxide or silicon nitride to be embedded in the trenches 121 and 122 and the inter-pixel trench 123 may be embedded therein when forming the insulating layer 158. Aluminum oxide has high moisture resistance as a physical property. Therefore, aluminum oxide may be formed on the surfaces of the trenches 121 and 122 to improve the moisture resistance of each of the chip guard ring portion 1022 and the pad guard ring portion 1024. As shown in FIG. 11, the main surface 102 of the semiconductor layer 110 and the surfaces of the trenches 121 and 122 and the inter-pixel trench 123 are continuously covered using aluminum oxide as the fixed charge film 156. With this, the moisture resistant function can be effectively improved.

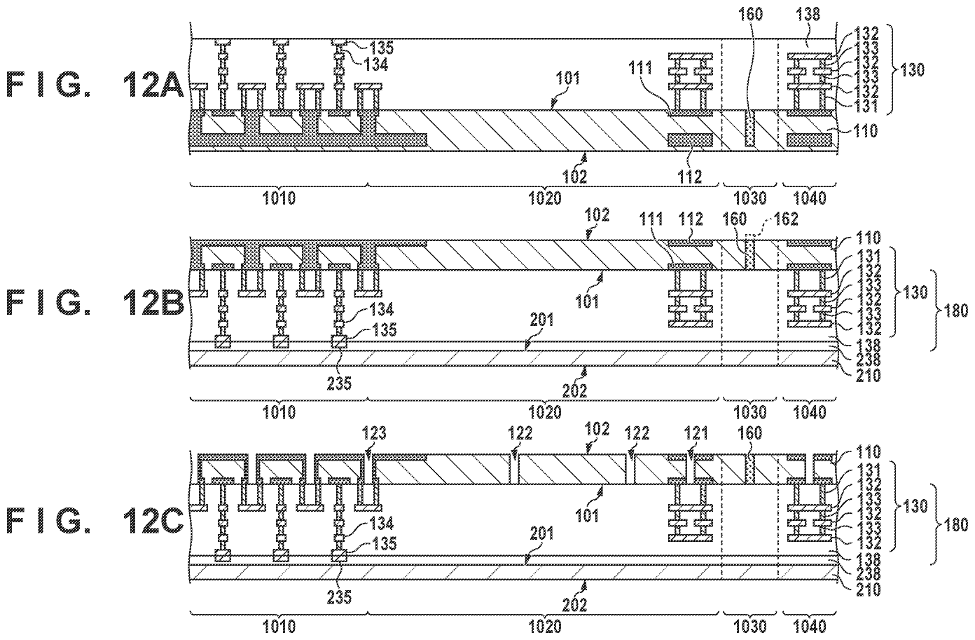

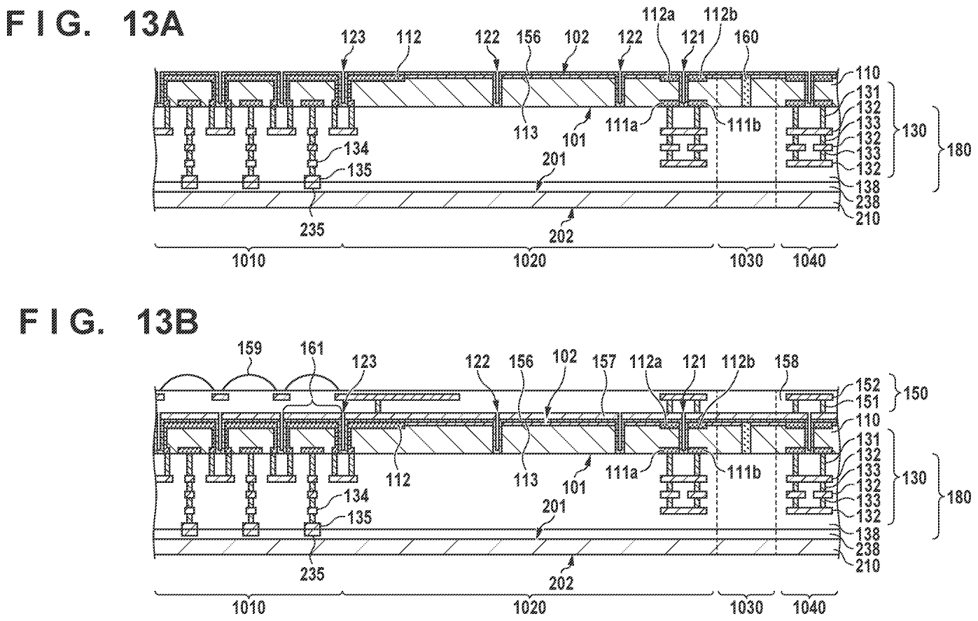

FIGS. 12A to 13B are views showing an example of the manufacturing process of the semiconductor device 1001 having the sectional structure shown in FIG. 11. First, an exposure mark trench 160 used when processing the main surface 102 side of the semiconductor layer 110 is formed from the main surface 101 side of the semiconductor layer 110. For example, silicon nitride or the like is embedded in the exposure mark trench 160. The material to be embedded in the exposure mark trench 160 may be, for example, silicon oxide or the like, as long as it can be used as an exposure mark. On the other hand, a metal material may not be embedded in the exposure mark trench 160 since the metal material can become a metal contamination source in subsequent steps.

After the exposure mark trench 160 is formed, an n-type semiconductor region 111 (which forms the semiconductor regions 111a and 111b described above), and a p-type semiconductor region 112 (which forms the semiconductor regions 112, 112a, and 112b described above) are formed by, for example, ion implantation using an n-type dopant and a p-type dopant, respectively. After this, the insulating layer 138 arranged on the main surface 101 of the semiconductor layer 110, the conductive members 131 and 133 and the wiring patterns 132 arranged in the insulating layer 138, and the like are formed. Further, the joint via 134, the joint metal 135, and the like are also formed. At this time, as shown in FIG. 12A, the conductive path 130 in the chip guard ring portion 1022 is formed.

Then, as shown in FIG. 12B, the semiconductor layer 110 is reversed, and the insulating layer 138 formed on the main surface 101 of the semiconductor layer 110 and the insulating layer 238 formed on the main surface 201 of the semiconductor layer 210 are joined via the joint surface 500. Thus, the semiconductor layer 110 and the semiconductor layer 210 are stacked. After the semiconductor layer 110 and the semiconductor layer 210 are stacked, the main surface 102 side of the semiconductor layer 110 is polished to decrease the thickness of the semiconductor layer 110.

Unlike the arrangement shown in FIG. 3, the merit of having the same structure for the trenches 121 and 122 and the inter-pixel trench 123 as shown in FIG. 11 is that scratch defects during polishing the main surface 102 side of the semiconductor layer 110 are suppressed. In the arrangement shown in FIG. 3, the trench 121 is formed at the same time as, for example, the exposure mark trench 160. In this case, in the step shown in FIG. 12B, when polishing the main surface 102 side of the semiconductor layer 110, the trench 121 is exposed at the same time as the exposure mark trench 160. Thus, not only a distal end portion 162 of the exposure mark trench 160 but also the distal end portion of the trench 121 is chipped, causing scratches. The arrangement shown in FIG. 11 suppresses the scratch defects.

Then, as shown in FIG. 12C, the semiconductor layer 110 is etched from the main surface 102 side of the semiconductor layer 110 to form the trenches 121 and 122 and the inter-pixel trench 123. At this time, there is a risk of metal contamination caused by a resist directly contacting the semiconductor layer 110. Therefore, an etching step including resist coating and the like may be performed after a hard mask made of aluminum oxide or the like is formed on the main surface 102 of the semiconductor layer 110.

Then, as shown in FIG. 13A, the fixed charge film 156 is formed. The fixed charge film 156 may be formed by, for example, depositing aluminum oxide using an Atomic Layer Deposition (ALD) method. The ALD method can perform deposition with high uniformity in film thickness and the like on the side walls and bottom portions of the trenches 121 and 122 and the inter-pixel trench 123.

Further, as shown in FIG. 13B, the insulating layer 158, the conductive member 151 and the wiring pattern 152 arranged in the insulating layer 158, and the like are formed on the main surface 102 of the semiconductor layer 110. At this time, the conductive path 150 using the conductive member 151 and the wiring pattern 152 is formed. By using these steps, the semiconductor device 1001 having the arrangement shown in FIG. 11 is formed.

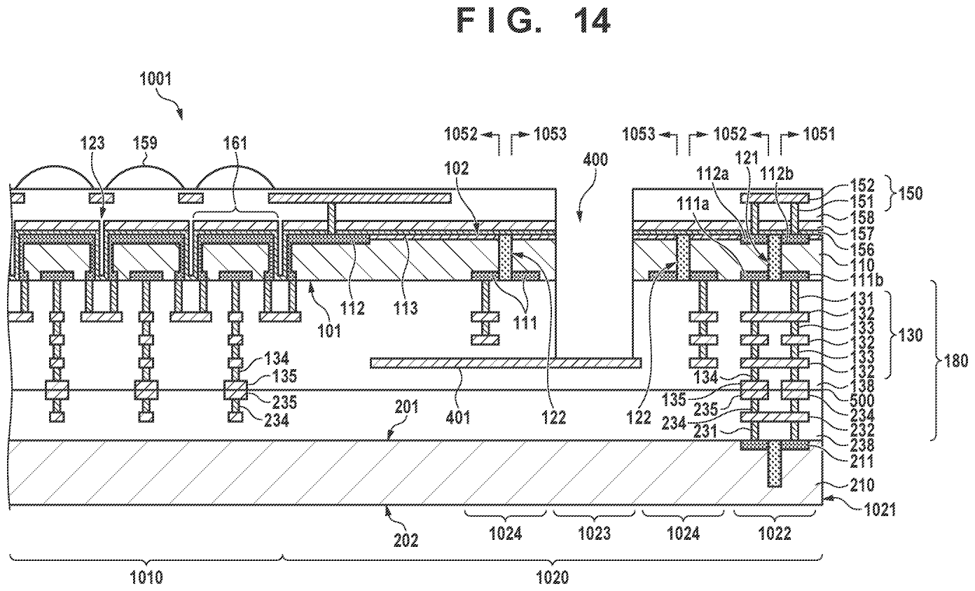

FIG. 14 is a view showing a modification of the sectional view shown in FIG. 3. In the arrangement shown in FIG. 14, an n-type semiconductor region 211 forming a part of the main surface 201 of the semiconductor layer 210 is arranged in the semiconductor layer 210. Further, a conductive member 231 and a wiring pattern 232 are arranged in the insulating layer 238 on the main surface 102 of the semiconductor layer 210. Furthermore, the conductive path 130, which electrically connects the semiconductor region 111a and the semiconductor region 111b, is connected to the semiconductor region 211 in the semiconductor layer 210 via the joint vias 134 and 234, the joint metals 135 and 235, the wiring pattern 232, and the conductive member 231. With this arrangement, a strong electric path can be obtained for the conductive path 130. In addition, it is possible to set a potential for avoiding the floating state from the semiconductor layer 210 side, and this improves the degree of freedom in design.

Along the outer edge 1021 of the semiconductor device 1001, the conductive members 131, 133, and 231, the wiring patterns 132 and 232, the joint vias 134 and 234, and the joint metals 135 and 235, for each of which a metal is used, are arranged. Silicon oxide which can be used for the insulating layer 180 (insulating layers 138 and 238) has a low moisture resistance as compared to a metal. On the other hand, in the arrangement shown in FIG. 14, metal materials are arranged in the insulating layer 180 along the outer edge 1021 of the semiconductor device 1001 so as to surround the outer peripheral portion of the semiconductor device 1001. With this, the moisture resistance of the chip guard ring portion 1022 can be improved.

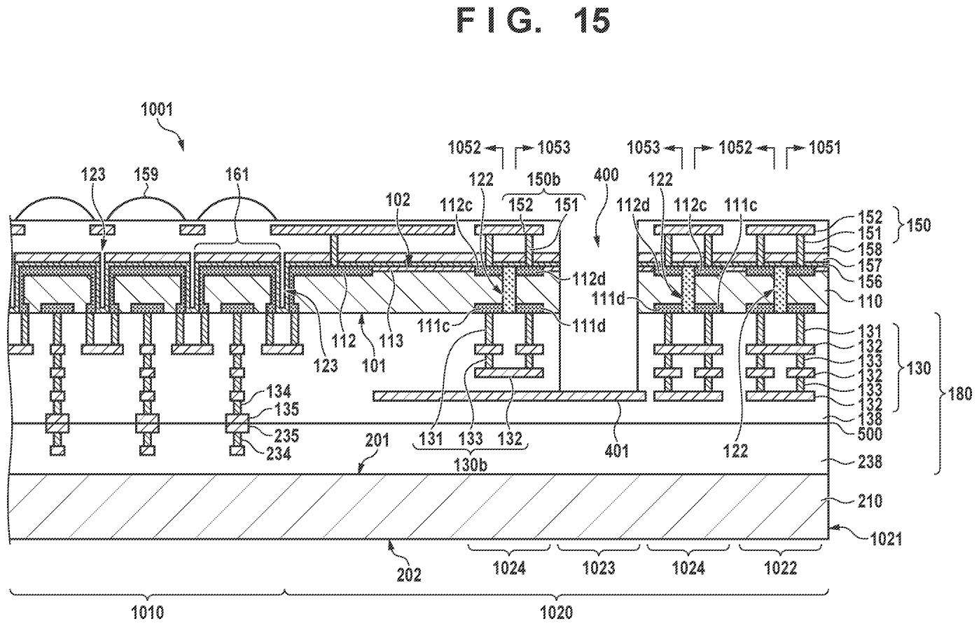

FIG. 15 is a view showing a modification of the sectional view shown in FIG. 3. In the arrangement shown in FIG. 3, the portion 1053 of the semiconductor layer 110 exposed to the opening portion 400 is electrically separated from the portion 1052 and in the floating state. On the other hand, in the arrangement shown in FIG. 15, a conductive path is provided to prevent the portion 1053 from entering the floating state. More specifically, the portion 1052 includes an n-type semiconductor region 111c forming a part of the main surface 101 of the semiconductor layer 110, and a p-type semiconductor region 112c forming a part of the main surface 102 of the semiconductor layer 110. Further, the portion 1053 includes an n-type semiconductor region 111d forming a part of the main surface 101 of the semiconductor layer 110, and a p-type semiconductor region 112d forming a part of the main surface 102 of the semiconductor layer 110. A conductive path 130b using the conductive members 131 and 133 and the wiring patterns 132 for electrically connecting the semiconductor region 111c and the semiconductor region 111d is arranged in the insulating layer 180. Similarly, a conductive path 150b using the conductive member 151 and the wiring pattern 152 for electrically connecting the semiconductor region 112c and the semiconductor region 112d is arranged in the insulating layer 158.

The portion 1053 of the semiconductor layer 110 exposed to the opening portion 400 also enters the floating state. Therefore, the conductive paths 130b and 150b electrically connecting the portion 1052 and the portion 1053 may also be arranged in the pad guard ring portion 1024. Since the area of the portion 1053 of the semiconductor layer 110 is smaller than the area of the portion 1051 in contact with the outer edge 1021 of the semiconductor device 1001, a risk of a problem caused by the portion 1053 entering the floating state is low. Hence, only one of the conductive paths 130b and 150b may be arranged. Alternatively, as shown in FIG. 15, both the conductive path 130b and the conductive path 150b may be arranged.

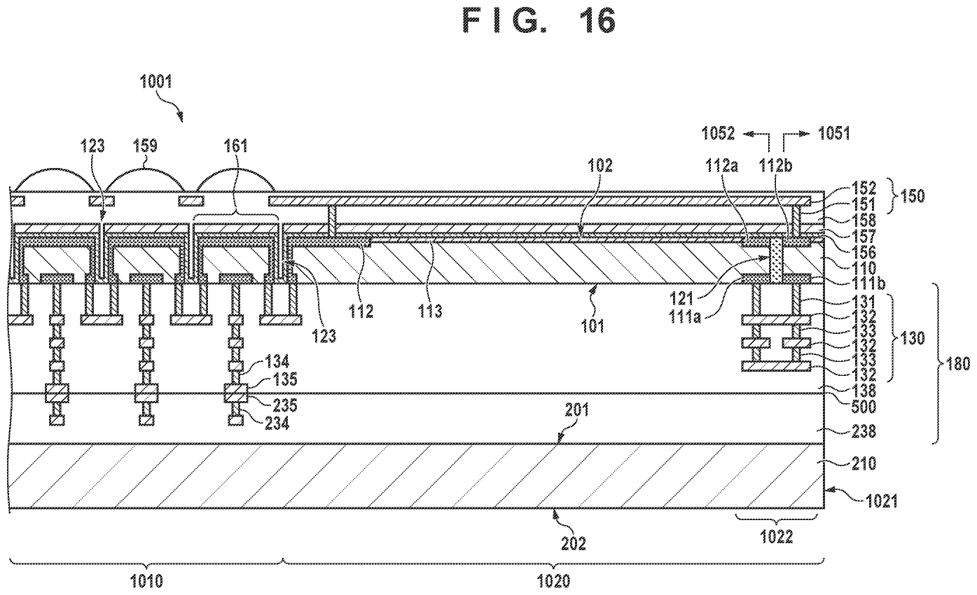

FIG. 16 is a view showing a modification of the sectional view shown in FIG. 2. As compared to the arrangement shown in FIG. 2, the wiring pattern 152 used for the conductive path 150 arranged in the insulating layer 158 and the wiring pattern 152 provided in the pixel portion 1010 are directly connected. With this, an electric path having a higher conductivity than the above-described electric path 802b passing through the semiconductor layer 110 can be used. Therefore, it is possible to reduce the time lag with respect to the applied voltage, thereby quickly avoiding the floating.

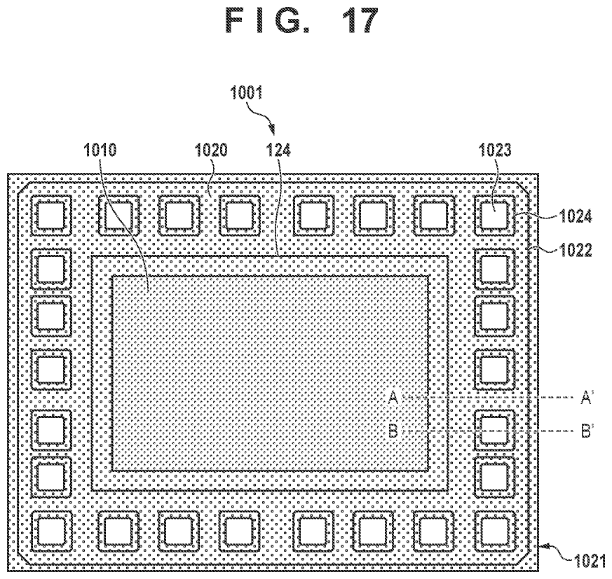

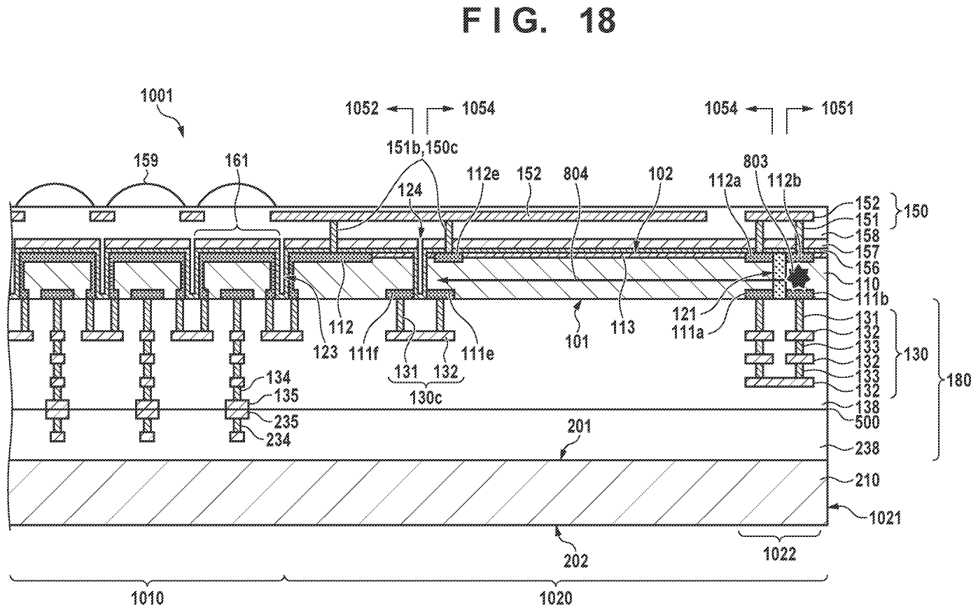

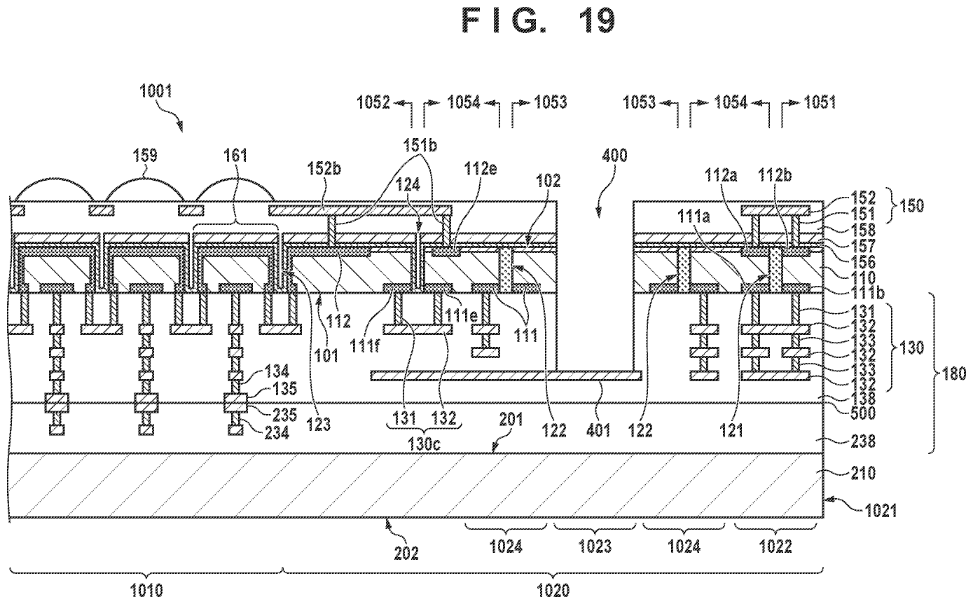

It has been described above that the p-n junction portion 803 exists in the chip guard ring portion 1022, so that the p-n junction portion 803 can become a light emission source if a large current flows in the direction of a forward junction, and this can affect an obtained image. To prevent this, with reference to FIGS. 17 to 19, the structure of the semiconductor device 1001 that copes with light emission in the chip guard ring portion 1022 will be described. FIG. 17 is a top view of the semiconductor device 1001, FIG. 18 is a sectional view showing the arrangement example taken along the line A-A′ in FIG. 17, and FIG. 19 is a sectional view showing the arrangement example taken along the line B-B′ in FIG. 17. FIG. 18 is the sectional view not including the pad opening portion 1023, and FIG. 19 is the sectional view including the pad opening portion 1023.

As compared to the arrangement shown in FIGS. 1 to 3 described above, in the arrangement shown in FIGS. 17 to 19, a trench 124 for shielding light is arranged in the peripheral circuit portion 1020. The arrangement except for the trench 124 may be similar to the arrangement shown in FIGS. 1 to 3. Therefore, the trench 124 will be mainly described here, and a description of the arrangement that may be similar to the arrangement shown in FIGS. 1 to 3 will be omitted, as appropriate.

As has been described above, in this embodiment, in order to prevent the p-n junction portion 803 from becoming the light emission source, the conductive path 150 is provided to for the electric path 802b. However, there is a possibility that the electric path 802b sufficient to avoid the p-n junction portion 803 is not formed due to a high resistance value of the conductive member 151 or a high contact resistance between the conductive member 151 and each of the semiconductor regions 112a and 112b caused by variations in the manufacture. In this case, the p-n junction portion 803 in the chip guard ring portion 1022 may become a light emission source, and light may enter the pixel portion 1010 via a path 804, causing a problem that an obtained image is affected. In such a case, arranging the trench 124 having the arrangement similar to that of the inter-pixel trench 123 arranged in the pixel portion 1010 is effective since it can shield light in the path 804.

However, when the trench 124 is arranged so as to surround the pixel portion 1010 as shown in FIG. 17, the trench 124 electrically separates the semiconductor layer 110 between the portion 1051 and the portion 1054 and between the portion 1052 and the portion 1054. Then, if the portion 1054 enters a floating state, a problem caused by the floating state may occur as has been described above.

To prevent this, the portion 1054 of the semiconductor layer 110 includes a p-type semiconductor region 112e forming a part of the main surface 102 of the semiconductor layer 110. A conductive path 150c using the wiring pattern 152 and a conductive member 151b that electrically connect the p-type semiconductor region 112e in the portion 1054 and the p-type semiconductor region 112 in the portion 1052 is arranged in the insulating layer 158. The portion 1052 of the semiconductor layer 110 includes an n-type semiconductor region 111f forming a part of the main surface 101, and the portion 1054 includes an n-type semiconductor region 111e forming a part of the main surface 101. A conductive path 130c using the wiring pattern 132 and the conductive member 131 that electrically connect the n-type semiconductor region 111e in the portion 1054 and the n-type semiconductor region 111f in the portion 1052 is arranged in the insulating layer 138. With this, a problem caused by the floating state can be suppressed.

In the arrangement shown in FIGS. 18 and 19, the conductive path 150 and the conductive path 150c are electrically connected via the semiconductor layer 110 such as the hole inducing layer 113. That is, the wiring pattern 152 is arranged while being separated into a portion forming the conductive path 150 and a portion forming the conductive path 150c. However, in the wiring pattern 152, the portion forming the conductive path 150 and the portion forming the conductive path 150c may be continuous. That is, the trench 124 for shielding light may be arranged in the arrangement as shown in FIG. 16.

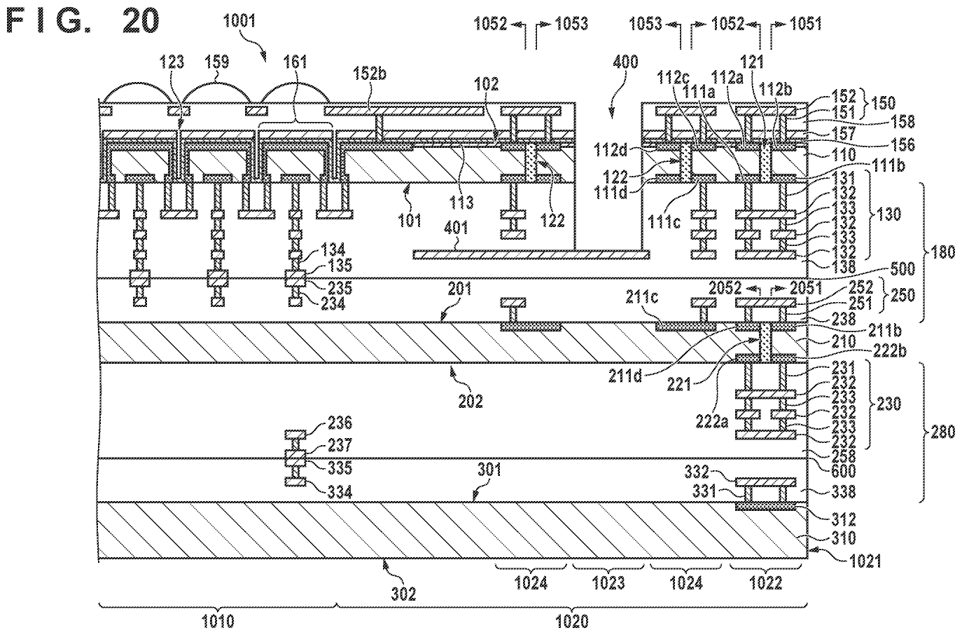

With reference to FIGS. 20 to 22, modifications of the semiconductor device 1001 will be described. Each of FIGS. 20 to 22 shows an arrangement in which a semiconductor layer 310 is stacked in addition to the above-described semiconductor layers 110 and 210.

As shown in FIG. 20, an insulating layer 280 is arranged in contact with the main surface 202 of the semiconductor layer 210 on the opposite side of the main surface 201 facing the semiconductor layer 110. The semiconductor layer 310 is stacked via the insulating layer 280. The semiconductor layer 310 includes a main surface 301 in contact with the insulating layer 280, and a main surface 302 on the opposite side of the main surface 301. The insulating layer 280 arranged between the semiconductor layer 210 and the semiconductor layer 310 includes an insulating layer 258 in contact with the main surface 202 of the semiconductor layer 210, and an insulating layer 338 in contact with the main surface 301 of the semiconductor layer 310. The insulating layer 258 and the insulating layer 338 are joined at a joint surface 600 via joint metals 237 and 335 and joint vias 236 and 334.

The semiconductor layer 210 is divided into a portion 2051 and a portion 2052 electrically separated in the semiconductor layer 210 by a trench 221 extending through the semiconductor layer 210 arranged in the chip guard ring portion 1022. A semiconductor element such as a transistor can be arranged in the portion 2052. The portion 2051 includes an n-type semiconductor region 211b forming a part of the main surface 201 of the semiconductor layer 210, and a p-type semiconductor region 212b forming a part of the main surface 202 of the semiconductor layer 210. The portion 2052 includes an n-type semiconductor region 211a forming a part of the main surface 201 of the semiconductor layer 210, and a p-type semiconductor region 212a forming a part of the main surface 202 of the semiconductor layer 210. A conductive path 250 using a conductive member 251 and a wiring pattern 252 for electrically connecting the semiconductor region 211a and the semiconductor region 211b is arranged in the insulating layer 180. Further, a conductive path 230 using the conductive members 231 and 233 and a wiring pattern 232 for electrically connecting the semiconductor region 212a and the semiconductor region 212b is arranged in the insulating layer 280. With this, the portions 2051 and 2052 of the semiconductor layer 210 are electrically connected, thereby preventing chipping of the semiconductor layer 210 and preventing the end portion (portion 2051) of the semiconductor layer 210 from entering a floating state. In this manner, even if the number of semiconductor layers to be stacked increases, conductive paths of two conductivity types can be provided.

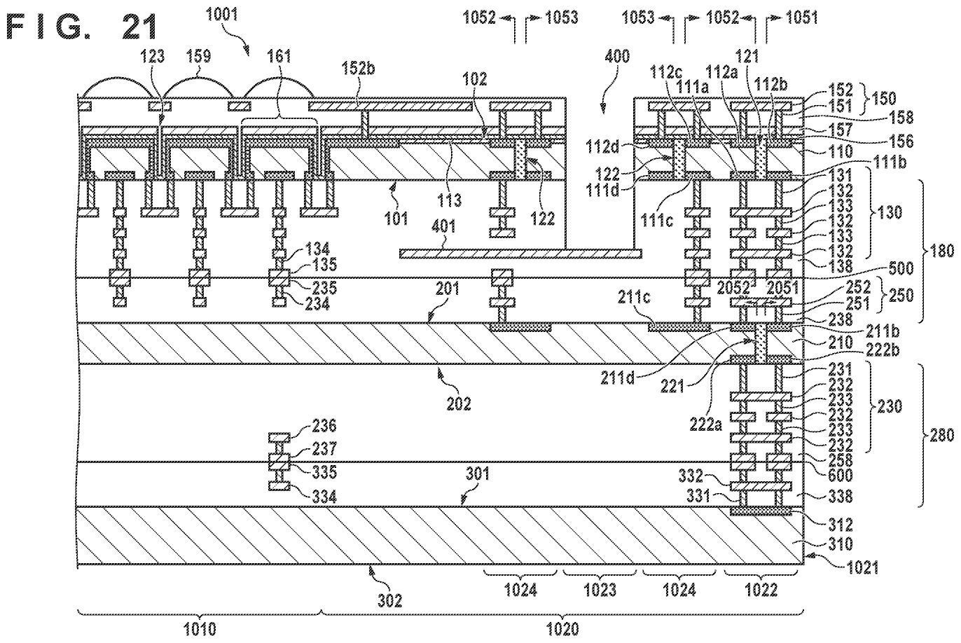

FIG. 21 is a view showing a modification of the sectional view shown in FIG. 20. As shown in FIG. 21, the conductive path 130 and the conductive path 250 may be electrically connected. Further, the conductive path 230 is electrically connected to the semiconductor layer 310 via the conductive members 231, 233, and 331, the wiring patterns 232 and 332, the joint metals 237 and 335, and the joint vias 236 and 334. A p-type semiconductor region 312 is provided in the main surface 301 of the semiconductor layer 310, and the conductive path 230 may be connected to the semiconductor region 312.

With this arrangement, a strong electric path can be obtained for the conductive paths 130, 250, and 230. In addition, it is possible to set a potential for avoiding the floating state from the semiconductor layers 210 and 310 side, and this improves the degree of freedom in design.

Along the outer edge 1021 of the semiconductor device 1001, the conductive members 131, 133, 231, 233, 251, and 331, the wiring patterns 132, 232, 252, and 332, the joint vias 134, 234, 236, and 334, and the joint metals 135, 235, 237, and 335, for each of which a metal is used, are arranged. Silicon oxide which can be used for the insulating layers 180 and 280 has a low moisture resistance as compared to a metal. On the other hand, in the arrangement shown in FIG. 21, metal materials are arranged in the insulating layers 180 and 280 along the outer edge 1021 of the semiconductor device 1001 so as to surround the outer peripheral portion of the semiconductor device 1001. With this, the moisture resistance of the chip guard ring portion 1022 can be improved.

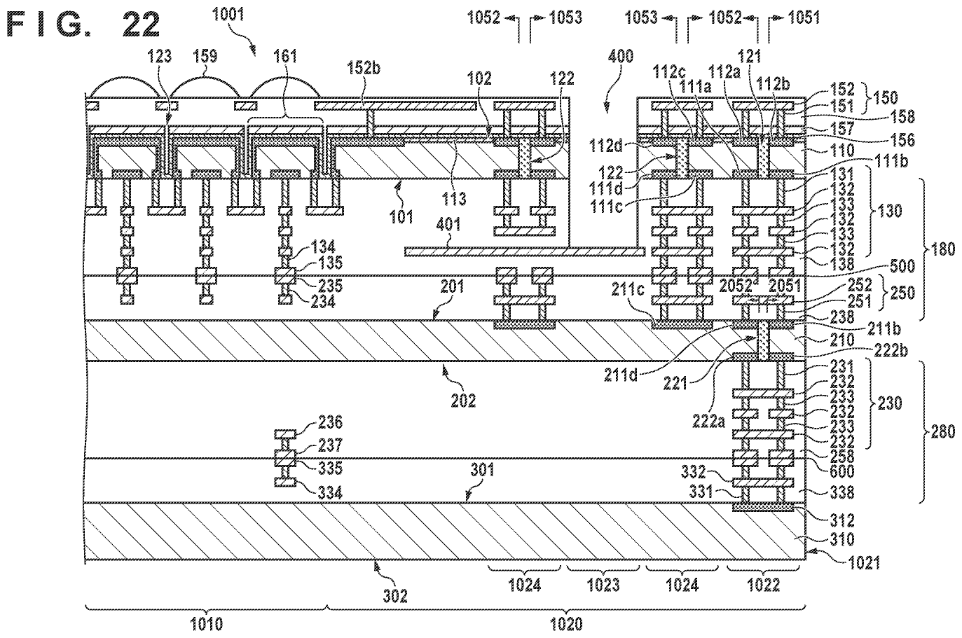

FIG. 22 is a view showing a modification of the sectional view shown in FIG. 21. As in the arrangement shown in FIG. 15, a conductive path may be provided to prevent the portion 1053 of the semiconductor layer 110 around the pad opening portion 1023 from entering a floating state as shown in FIG. 22.

Further, a conductive path connecting the semiconductor regions 111c and 111d in the portion 1053 of the semiconductor layer 110 may be electrically connected to the semiconductor layer 210. In this case, an n-type semiconductor region 211c may be provided in the main surface 201 of the semiconductor layer 210, and the conductive path connecting the semiconductor regions 111c and 111d may be connected to the semiconductor region 211c.

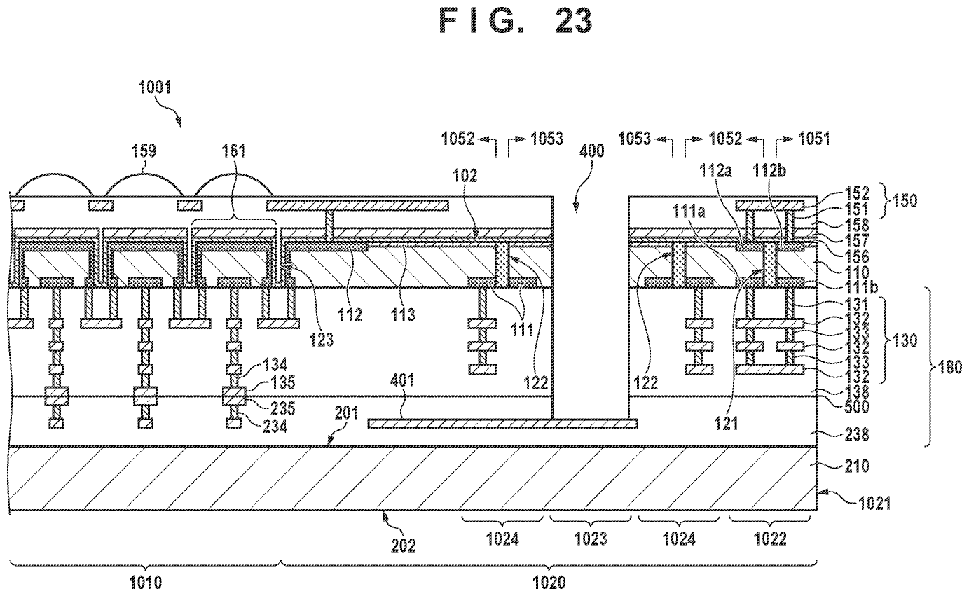

With reference to FIGS. 23 to 26, further modifications of the semiconductor device 1001 will be described. Each of FIGS. 23 to 26 shows a modification of the position of the electrode pad 401 in each embodiment described above.

FIG. 23 is a view showing a modification of the sectional view shown in FIG. 3. In the arrangement shown in FIG. 3, the electrode pad 401 is arranged in the insulating layer 138 of the insulating layer 180. On the other hand, in the arrangement shown in FIG. 23, the electrode pad 401 is arranged in the insulating layer 238 of the insulating layer 180. The position of the electrode pad 401 can be formed at the same time as a wiring pattern (for example, the wiring pattern 132) or the like. The electrode pad 401 may be arranged at an appropriate height in accordance with the arrangement of the wiring pattern or the like, as appropriate.

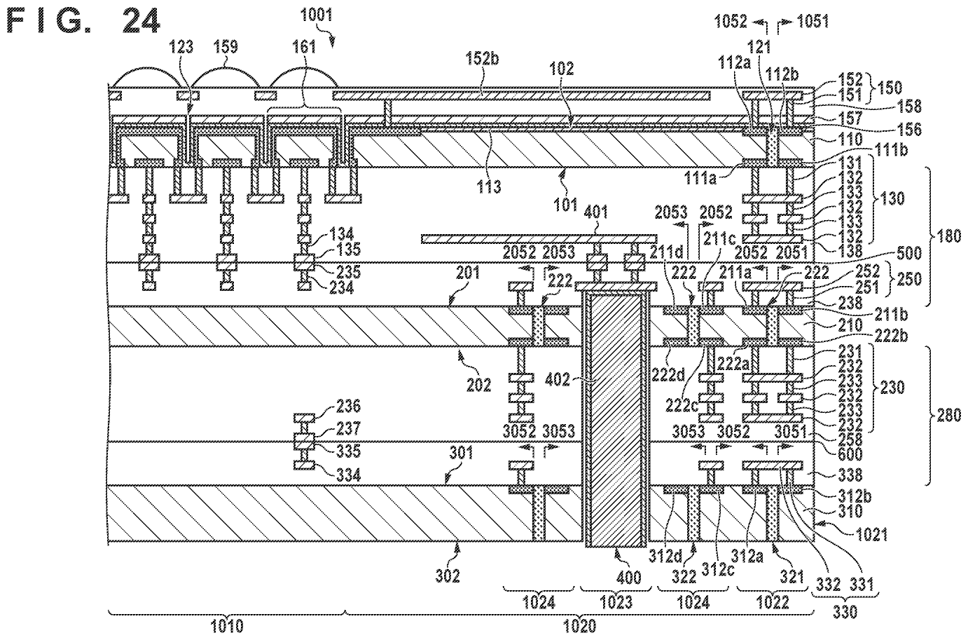

FIGS. 24 to 26 are views showing modifications of the sectional views shown in FIGS. 20 to 22. In the arrangement shown in each of FIGS. 20 to 22, the opening portion 400 is arranged from the semiconductor layer 110 side toward the electrode pad 401. On the other hand, in the arrangement shown in each of FIGS. 24 to 26, the opening portion 400 is arranged from the semiconductor layer 310 side toward the electrode pad 401, and extends through the semiconductor layers 210 and 310. Each of FIGS. 24 to 26 also shows a conductor 402 connected to the electrode pad 401.

As has been described above, the pixel 161 is arranged in the semiconductor layer 110. When the opening portion 400 is not provided in the semiconductor layer 110 where the pixel 161 is arranged, it is unnecessary to provide the trench 122 in the semiconductor layer 110. Accordingly, the portion 1053, which needs a countermeasure against the floating state, is not arranged in the semiconductor layer 110. Hence, the reliability of the semiconductor layer 110 where many semiconductor elements such as the pixel 161 are arranged improves.

In the arrangement shown in each of FIGS. 24 to 26, from the viewpoint of the pad guard ring portion 1024 which needs a countermeasure against the floating state, arranging the electrode pad 401 between the semiconductor layer 210 and the semiconductor layer 310 eliminates a portion 2053 generated due to a trench 222 in the semiconductor layer 210. However, in a case in which, for example, the semiconductor device 1001 functions as a SPAD sensor, an arrangement in which high-voltage negative charges are directly applied to the semiconductor layer 110 arranged with the pixel 161 without intervening the semiconductor layers 210 and 310 can be less difficult to process the opening portion 400. Therefore, in the arrangement shown in each of FIGS. 24 to 26, the electrode pad 401 is arranged in the insulating layer 180 between the semiconductor layer 110 and the semiconductor layer 210.

In the arrangement shown in each of FIGS. 24 to 26, the trench 222 extending through the semiconductor layer 210 so as to electrically separate the portion 2052 and the portion 2053 in the semiconductor layer 210 is arranged in the semiconductor layer 210. A trench 322 extending through the semiconductor layer 310 so as to electrically separate a portion 3052 and a portion 3053 in the semiconductor layer 310 is arranged in the semiconductor layer 310. Each of the trenches 222 and 322 can have an arrangement similar to the arrangement of the trench 122 which is arranged in the semiconductor layer 110 when arranging the opening portion 400 extending through the semiconductor layer 110.

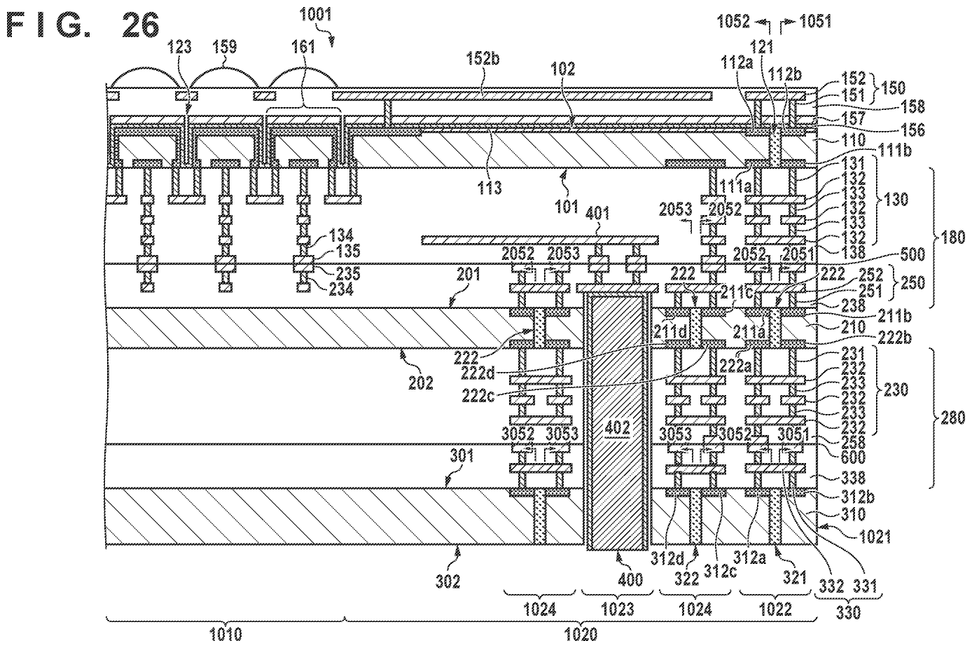

In addition, when the trench 222 is arranged, the n-type semiconductor region 211c and an n-type semiconductor region 211d can be arranged in the main surface 201 of the semiconductor layer 210, and p-type semiconductor regions 212c and 212d can be arranged in the main surface 202 of the semiconductor layer 210. As shown in FIG. 26, the semiconductor region 211c and the semiconductor region 211d may be electrically connected by a conductive path, and the semiconductor region 212c and the semiconductor region 212d may be electrically connected by a conductive path. This suppresses the floating state of the portion 2053. Similarly, when the trench 322 is arranged, p-type semiconductor regions 312c and 312d can be arranged in the main surface 301 of the semiconductor layer 310. As shown in FIG. 26, the semiconductor region 312c and the semiconductor region 312d may be electrically connected by a conductive path. This suppresses the floating state of the portion 3053.

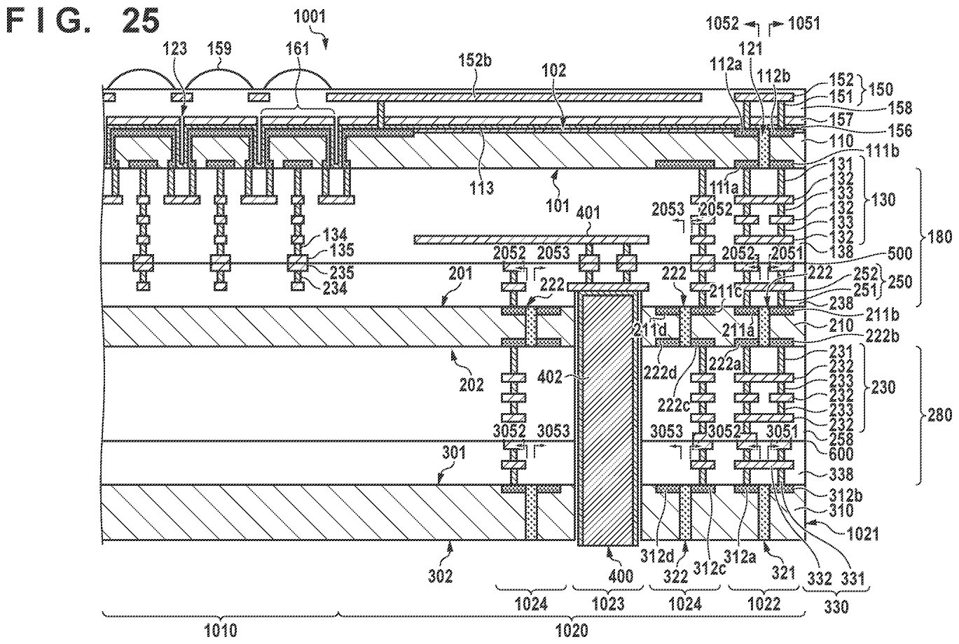

Further, as shown in each of FIGS. 24 to 26, the semiconductor layer 310 may be divided into a portion 3051 and the portion 3052 electrically separated in the semiconductor layer 310 by a trench 321 extending through the semiconductor layer 310 arranged in the chip guard ring portion 1022. A semiconductor element such as a transistor can be arranged in the portion 3052. The portion 3051 includes a p-type semiconductor region 312b forming a part of the main surface 301 of the semiconductor layer 310. The portion 3052 includes a p-type semiconductor region 312a forming a part of the main surface 301 of the semiconductor layer 310. A conductive path 330 using the conductive member 331 and the wiring pattern 332 for electrically connecting the semiconductor region 312a and the semiconductor region 312b may be arranged in the insulating layer 280. With this, the portions 3051 and 3052 of the semiconductor layer 310 are electrically connected. This may prevent chipping of the semiconductor layer 310, and prevent the end portion (portion 3051) of the semiconductor layer 310 from entering a floating state. As shown in FIGS. 25 and 26, the conductive path 330 may be electrically connected to the conductive path 230.

Similar to the main surface 102 side of the semiconductor layer 110, an insulating layer may be arranged on the main surface 302 of the semiconductor layer 310. In this case, via conductive members and wiring patterns arranged in the insulating layer on the main surface 302 of the semiconductor layer 310, the portions 3051 and 3052 of the insulating layer 310 may be electrically connected, and the portions 3052 and 3053 thereof may be electrically connected.

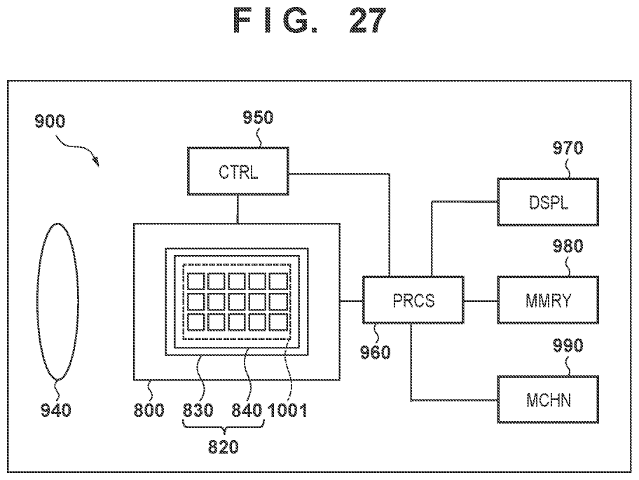

An apparatus 900 including the semiconductor device 1001 according to the embodiment shown in FIG. 27 will be described below in detail. The semiconductor device 1001 is accommodated in a package 820 and mounted in the apparatus 900. An electronic component 800 can include the package 820 including a base 830 on which the semiconductor device 1001 is fixed and a cover 840 made of glass or the like facing the semiconductor device 1001. A bonding member such as a wire and bump for connecting an internal terminal of the base 830 and a terminal such as the electrode pad 401 of the semiconductor device 1001 can be arranged in the package 820.

The apparatus 900 can include at least one of the optical device 940, the control device 950, the processing device 960, the display device 970, the storage device 980, and the mechanical device 990. The optical device 940 is implemented by, for example, a lens, a shutter, and a mirror. The control device 950 controls the semiconductor device 1001. The control device 950 is, for example, a semiconductor device such as an ASIC.

The processing device 960 processes a signal output from the semiconductor device 1001. The processing device 960 is a semiconductor device such as a CPU or an ASIC for forming an analog front end (AFE) or a digital front end (DFE). The display device 970 is an EL display device or a liquid crystal display device that displays information (image) obtained by the semiconductor device 1001. The storage device 980 is a magnetic device or a semiconductor device that stores the information (image) obtained by the semiconductor device 1001. The storage device 980 is a volatile memory such as an SRAM or a DRAM, or a nonvolatile memory such as a flash memory or a hard disk drive.

The mechanical device 990 includes a moving or propulsion unit such as a motor or an engine. In the apparatus 900, the signal output from the semiconductor device 1001 is displayed on the display device 970 or transmitted to an external device by a communication device (not shown) included in the apparatus 900. Hence, the apparatus 900 may further include the storage device 980 and the processing device 960 in addition to the memory circuits and arithmetic circuits included in the semiconductor device 1001. The mechanical device 990 may be controlled based on the signal output from the semiconductor device 1001.

In addition, the apparatus 900 is suitable for an electronic apparatus such as an information terminal (for example, a smartphone or a wearable terminal) which has a shooting function or a camera (for example, an interchangeable lens camera, a compact camera, a video camera, or a monitoring camera). The mechanical device 990 in the camera can drive the components of the optical device 940 in order to perform zooming, an in-focus operation, and a shutter operation. Alternatively, the mechanical device 990 in the camera can move the semiconductor device 1001 in order to perform an anti-vibration operation.

Furthermore, the apparatus 900 can be a transportation apparatus such as a vehicle, a ship, or an airplane. The mechanical device 990 in the transportation apparatus can be used as a moving device. The apparatus 900 as the transportation apparatus is suitable for a device that transports the semiconductor device 1001 or a device that uses an image capturing function to assist and/or automate driving (steering). The processing device 960 for assisting and/or automating driving (steering) can perform, based on the information obtained by the semiconductor device 1001, processing for operating the mechanical device 990 as a moving device. Alternatively, the apparatus 900 may be a medical apparatus such as an endoscope, a measurement apparatus such as a distance measurement sensor, an analysis apparatus such as an electron microscope, an office apparatus such as a copy machine, or an industrial apparatus such as a robot.

According to the present invention, it is possible to provide a technique advantageous in suppressing occurrence of a problem of a semiconductor element.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-045788, filed Mar. 22, 2023, which is hereby incorporated by reference herein in its entirety.

What is claimed is:

1. A semiconductor device that comprises a semiconductor layer comprising a first main surface and a second main surface on an opposite side of the first main surface, a first insulating layer arranged in contact with the first main surface, and a second insulating layer arranged in contact with the second main surface, wherein
the semiconductor layer includes a first portion and a second portion, which are electrically separated in the semiconductor layer by a trench extending through the semiconductor layer, and a semiconductor element is arranged in the second portion,
the first portion includes a first semiconductor region of a first conductivity type which forms a part of the first main surface, and a second semiconductor region of a second conductivity type opposite to the first conductivity type which forms a part of the second main surface,
the second portion includes a third semiconductor region of the first conductivity type which forms a part of the first main surface, and a fourth semiconductor region of the second conductivity type which forms a part of the second main surface,
a first conductive path configured to electrically connect the first semiconductor region and the third semiconductor region is arranged in the first insulating layer, and
a second conductive path configured to electrically connect the second semiconductor region and the fourth semiconductor region is arranged in the second insulating layer.

2. The device according to claim 1, wherein
the semiconductor element includes a fifth semiconductor region of the second conductivity type, and
the fourth semiconductor region is electrically connected to the fifth semiconductor region.

3. The device according to claim 1, wherein
the semiconductor element includes at least one of a photodiode and an avalanche photodiode.

4. The device according to claim 1, wherein
an insulator is embedded in the trench.

5. The device according to claim 4, wherein
one of a metal and a metal oxide is arranged between the insulator and a surface of the trench.

6. The device according to claim 1, wherein
the first portion is arranged so as to surround the second portion.

7. The device according to claim 1, wherein
the first portion forms at least a part of an outer edge of the semiconductor layer.

8. The device according to claim 1, wherein
the semiconductor layer further includes a third portion arranged between the first portion and an outer edge of the semiconductor layer,
the trench is used as a first trench, and a second trench extending through the semiconductor layer so as to electrically separate the first portion and the third portion in the semiconductor layer is arranged in the semiconductor layer,
the first portion further includes a sixth semiconductor region of the first conductivity type which forms a part of the first main surface, and a seventh semiconductor region of the second conductivity type which forms a part of the second main surface,
the third portion includes an eighth semiconductor region of the first conductivity type which forms a part of the first main surface, and a ninth semiconductor region of the second conductivity type which forms a part of the second main surface,
a third conductive path configured to electrically connect the sixth semiconductor region and the eighth semiconductor region is arranged in the first insulating layer, and
a fourth conductive path configured to electrically connect the seventh semiconductor region and the ninth semiconductor region is arranged in the second insulating layer.

9. The device according to claim 8, wherein
the second conductive path and the fourth conductive path are electrically connected.

10. The device according to claim 1, wherein
the semiconductor layer is used as a first semiconductor layer, and the device further comprises a second semiconductor layer stacked on the first semiconductor layer via the first insulating layer.

11. The device according to claim 10, wherein
an electrode pad for external connection is arranged in the first insulating layer,
an opening portion extending through the first semiconductor layer and configured to expose the electrode pad is arranged in the first semiconductor layer,
the first semiconductor layer further includes a fourth portion between the second portion and the opening portion so as to surround the opening portion,
the trench is used as a first trench, and a third trench extending through the first semiconductor layer so as to electrically separate the second portion and the fourth portion in the first semiconductor layer is arranged in the first semiconductor layer,
the second portion further includes a 10th semiconductor region of the first conductivity type which forms a part of the first main surface, and an 11th semiconductor region of the second conductivity type which forms a part of the second main surface,
the fourth portion includes a 12th semiconductor region of the first conductivity type which forms a part of the first main surface, and a 13th semiconductor region of the second conductivity type which forms a part of the second main surface,
a fifth conductive path configured to electrically connect the 10th semiconductor region and the 12th semiconductor region is arranged in the first insulating layer, and
a sixth conductive path configured to electrically connect the 11th semiconductor region and the 13th semiconductor region is arranged in the second insulating layer.

12. The device according to claim 1, wherein
the semiconductor layer is used as a first semiconductor layer, and the device further comprises a second semiconductor layer stacked on the first semiconductor layer via the first insulating layer,
an electrode pad for external connection is arranged in the first insulating layer,
an opening portion extending through the first semiconductor layer and configured to expose the electrode pad is arranged in the first semiconductor layer,
the first portion is arranged so as to surround the opening portion, and
the second portion is arranged so as to surround the first portion.

13. The device according to claim 10, wherein
the first conductive path is electrically connected to the second semiconductor layer.

14. The device according to claim 10, wherein
the second semiconductor layer comprises a third main surface arranged in contact with the first insulating layer, and a fourth main surface on an opposite side of the third main surface, and includes a fifth portion and a sixth portion arranged between the fifth portion and an outer edge of the second semiconductor layer,
a fourth trench extending through the second semiconductor layer so as to electrically separate the fifth portion and the sixth portion in the second semiconductor layer is arranged in the second semiconductor layer,
the fifth portion includes a 14th semiconductor region of the first conductivity type which forms a part of the third main surface,
the sixth portion includes a 15th semiconductor region of the first conductivity type which forms a part of the third main surface, and
a seventh conductive path configured to electrically connect the 14th semiconductor region and the 15th semiconductor region is arranged in the first insulating layer.

15. The device according to claim 14, wherein
the first conductive path and the seventh conductive path are electrically connected.

16. The device according to claim 14, further comprising a third insulating layer arranged in contact with the fourth main surface,
wherein
the fifth portion includes a 16th semiconductor region of the second conductivity type which forms a part of the fourth main surface,
the sixth portion includes a 17th semiconductor region of the second conductivity type which forms a part of the fourth main surface, and
an eighth conductive path configured to electrically connect the 16th semiconductor region and the 17th semiconductor region is arranged in the third insulating layer.

17. The device according to claim 16, further comprising a third semiconductor layer stacked on the second semiconductor layer via the third insulating layer,
wherein the eighth conductive path is electrically connected to the third semiconductor layer.

18. The device according to claim 16, further comprising a third semiconductor layer stacked on the second semiconductor layer via the third insulating layer,
wherein
the third semiconductor layer comprises a fifth main surface arranged in contact with the third insulating layer, and a sixth main surface on an opposite side of the fifth main surface, and includes a seventh portion and an eighth portion arranged between the seventh portion and an outer edge of the third semiconductor layer,
a fifth trench extending through the third semiconductor layer so as to electrically separate the seventh portion and the eighth portion in the third semiconductor layer is arranged in the third semiconductor layer,
the seventh portion includes a 18th semiconductor region of the second conductivity type which forms a part of the fifth main surface,
the eighth portion includes a 19th semiconductor region of the second conductivity type which forms a part of the fifth main surface, and
a ninth conductive path configured to electrically connect the 18th semiconductor region and the 19th semiconductor region is arranged in the third insulating layer.

19. The device according to claim 18, wherein
the eighth conductive path and the ninth conductive path are electrically connected.

20. An apparatus comprising:
the semiconductor device according to claim 1; and
a processing device configured to process a signal output from the semiconductor device.
